(19) United States
(12) Patent Application Publication
(10) Pub. No.: US 2005/0112820 A1
(43) Pub. Date: May 26, 2005

(54) METHOD FOR FABRICATING FLASH MEMORY DEVICE AND STRUCTURE THEREOF

(76) Inventors: Jason Chen, Hsin-Chu Ken (TW); Ting-Chang Chang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,445

(22) Filed: Sep. 20, 2004

(30) Foreign Application Priority Data
Nov. 25, 2003 (TW) 92132993

(51) Int. Cl. H01L 21/336

(52) U.S. Cl. 438/257

(57) ABSTRACT

A method for fabricating a flash memory device is provided. A tunnel oxide layer is formed over a substrate. Thereafter, a floating gate, an inter-gate dielectric layer, and a control gate are sequentially formed over the tunnel oxide layer. Since the floating gate includes a plurality of nanocrystals, the memory cell can still normally function even if partial region of the floating gate is impaired.

### CROSS-REFERENCE TO RELATED APPLICATION

This application claims the priority benefit of Taiwan application serial no. 92132993, filed Nov. 25, 2003.

### BACKGROUND OF THE INVENTION

1. Field of Invention

The present invention relates to a method for fabricating a flash memory device and a structure thereof. More particularly, the present invention relates to a method for fabricating a flash memory device having a floating gate including a plurality of nanocrystals and a structure thereof.

2. Description of Related Art

Since data can be written, read and erased in flash memory device many times and the data saved in the flash memory device can be kept when the power is off. Therefore, the flash memory device has become a kind of non-volatile memory device widely used in personal computer (PC) and other electronic products.

Typically, the floating gate and the control gate (stacked gate structure) of the flash memory device is made of doped polysilicon, wherein the floating gate and the control gate are separated by an inter-gate dielectric layer, and the floating gate and the substrate are separated by a tunneling oxide layer.

When data is written in the flash memory device, a bias is applied between the control gate and the source/drain region so that electrons can be injected into the floating gate. When data is read from the flash memory device by applying an operating voltage to the control gate, a channel layer underneath is then turned on/off by the charged/uncharged-floating gate and a logical value “0” or “1” is obtained, respectively. When data is erased from the flash memory device, the electric potential of a substrate, the source region, the drain region or the control gate may be raised higher than that of the floating gate. In this manner, electrons may tunnel over a tunneling oxide from the floating gate to the substrate, the source region, the drain region (i.e. substrate erase or source or drain erase) or the control gate by tunneling effect. Therefore, data writing, reading or erasing of the flash memory device is related to the quality of the floating gate.

However, during the manufacturing process of the flash memory device, imperfections of process may result in local impaired region in the floating gate so that the impaired memory cell can not function normally. In other words, the local impaired region resulted from manufacturing process will influence the charge storage or the charge transmission characteristic in the floating gate. Therefore, during writing, reading or erasing of the flash memory device, the impaired memory cells thereof can not normally operate.

In another aspect, the local impaired region of the floating gate results in the failure of the memory cells and higher manufacturing cost. In addition, the floating gate may be impaired by factors other than the process imperfections. In other words, in order to improve the yield of the flash memory device, more operation conditions are necessary in manufacturing process or other related aspects. However, it is still an issue whether or not the costs invested in the processes can be balanced off by the profits of products.

### SUMMARY OF THE INVENTION

The invention provides a method for fabricating flash memory device and a structure thereof so as to resolve the failure issue of memory cells resulted from the local impaired region of the floating gate therein.

As embodied and broadly described herein, the invention provides a method for fabricating a flash memory device. The method comprises forming a tunneling oxide layer over a substrate. A floating gate having a plurality of nanocrystals and an inter-gate dielectric layer are formed over the tunneling oxide layer, wherein the material of the floating gate includes, for example, Si_{X}Ge_{1-X} or metal silicide. A control gate is formed over the inter-gate dielectric layer, wherein a stacked gate structure includes the tunneling oxide layer, the floating gate, the inter-gate dielectric layer and the control gate. Then, a source/drain region is formed in the substrate at each side of the stacked gate structure.

As embodied and broadly described herein, the invention provides a structure of flash memory device comprising a substrate, a tunneling oxide layer, a floating gate, and an inter-gate dielectric layer. The tunneling oxide layer is disposed over the substrate. The floating gate is disposed over the tunneling oxide layer. The floating gate includes a plurality of nanocrystals. The material of the floating gate includes, for example, Si_{X}Ge_{1-X} or metal silicide. The inter-gate dielectric layer covers over the nanocrystals and keeps the nanocrystals within the floating gate. The structure of flash memory device further comprises a control gate and a source/drain region. The control gate is disposed over the inter-gate dielectric layer. Also, the tunneling oxide layer, the floating gate, the inter-gate dielectric layer, and the control gate form a stacked gate structure. Furthermore, the source/drain region is formed in the substrate at each side of the stacked gate structure.

When the local region of the floating gate is impaired, only few of the crystals are impaired because the floating gate of the present invention includes the nanocrystals. Therefore, the charge storage or the charge transmission characteristic in the floating gate is not effectively affected, and thereby the failure issue of memory cells can be resolved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D schematically show a method for manufacturing the flash memory device of a preferred embodiment according to the present invention.

### DESCRIPTION OF THE PREFERRED EMBODIMENT

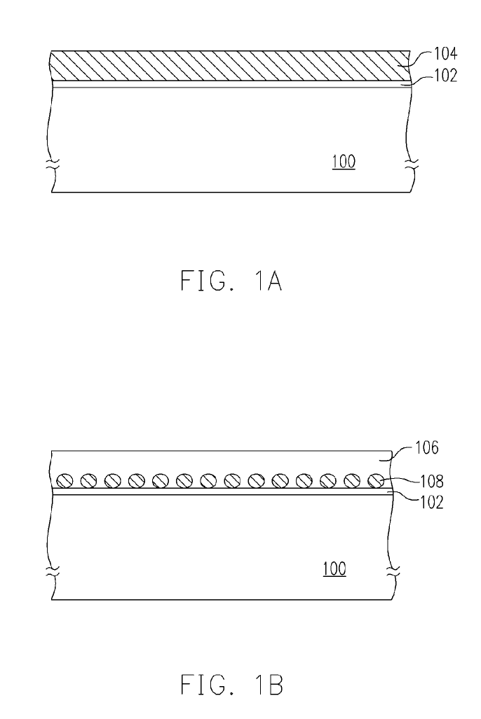

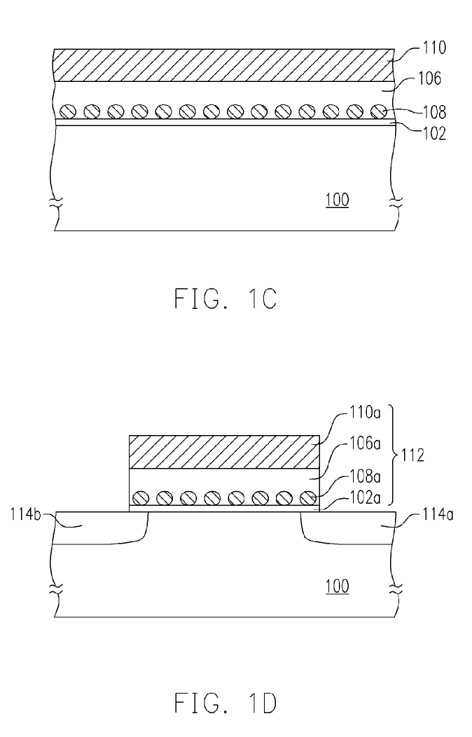

FIG. 1A to FIG. 1D schematically show a method for manufacturing the flash memory device of a preferred embodiment according to the present invention.

Referring to FIG. 1A, the method for manufacturing the flash memory device of the present invention comprises forming a tunneling oxide material layer 102 over a substrate 100. The material of the tunneling oxide material layer 102 includes, for example, silicon oxide, and the tunneling oxide material layer 102 may be formed by performing a thermal oxidation process. In an embodiment of the present invention, the thickness of the tunneling oxide material layer 102, for example, is about between 3.5 nm and 5.5 nm.

Referring to FIG. 1A, a charge storage layer 104 is then formed over the tunneling oxide material layer 102. The charge storage layer 104 may be formed by performing a low pressure chemical vapor deposition (LPCVD) process. In one embodiment of the present invention, the material of the charge storage layer 104 includes, for example, Si_{X}Ge_{1-X}. In another embodiment of the present invention, the material of the charge storage layer 104 includes, for example, metal silicide, such as tungsten silicide, titanium silicide, cobalt silicide or nickel silicide. Take tungsten silicide (W_{Y}Si_{Z}) as an example, the value of Y is about between 0.5 and 5, and the value of Z is about between 1 and 3.

In addition, according to various materials of the charge storage layer 104, the process parameters adopted for LPCVD process may be different. For example, in an embodiment of the present invention, when the material of the charge storage layer 104 is Si_{X}Ge_{1-X}, a reactive gas adopted for LPCVD process includes, for example, SiH₄ or GeH₄, an operating pressure, for example, is about between 1 and 1000 mTorrs, and a process temperature, for example, is about between 600 and 800 degrees centigrade.

Furthermore, in another embodiment of the present invention, when the material of the charge storage layer 104 is tungsten silicide, a reactive gas adopted for LPCVD process includes, for example, WF₆, SiH₄, Si₂H₆ or SiH₂Cl₂, an operating pressure, for example, is about between 1 and 1000 mTorrs, and a process temperature, for example, is about between 300 and 800 degrees centigrade.

Referring to FIG. 1B, a thermal oxidation process is then performed, and a portion of the charge storage layer 104 is oxidized to form an inter-gate dielectric material layer 106, such as silicon germanium oxide layer or metal silicon oxide layer. While, other portion of the charge storage layer 104 not being oxidized is converted into a plurality of nanocrystals. The nanocrystals mentioned above form a floating gate material layer 108. In an embodiment of the present invention, the thermal oxidation process, for example, is a rapid thermal oxidation process. During the rapid thermal oxidation process, gases including oxygen, such as O₂, H₂O or NOₓ, are provided. Furthermore, a process temperature of the rapid thermal oxidation process is about between 850 and 1000 degrees centigrade, and a more preferred process temperature is about 950 degrees centigrade.

It is noted that when the local region of the floating gate material layer 108 is impaired, only few of the crystals is impaired. Since the floating gate material layer 108 of the present invention includes the nanocrystals mentioned above, the floating gate material layer 108 can function normally via the region without impaired nanocrystals. Therefore, the charge storage or the charge transmission characteristic in the floating gate material layer 108 is not influenced.

Referring to FIG. 1C, a control gate material layer 110 is then formed over the inter-gate dielectric material layer 106. The material of the control gate material layer 110 includes, for example, doped polysilicon. The doped polysilicon may be formed by depositing an un-doped polysilicon layer, and then performing an ion implantation process. In addition, the control gate material layer 110 may be formed by performing an in-situ CVD process with reactive gases including dopants.

Referring to FIG. 1D, the tunneling oxide material layer 102, the floating gate material layer 108, the inter-gate dielectric material layer 106 and the control gate material layer 110 are then patterned to form a tunneling oxide layer 102a, a floating gate 108a, an inter-gate dielectric layer 106a and a control gate 110a, respectively. The tunneling oxide layer 102a, the floating gate 108a, the inter-gate dielectric layer 106a and the control gate 110a form a stacked gate structure 112. The method of patterning, for example, is a conventional photolithography/etch process.

Referring FIG. 1D, the manufacturing process is carried out by forming a source region 114a and a drain region 114b in the substrate 100 at each side of the stacked gate structure 112. The source region 114a and the drain region 114b, for example, is formed by performing a conventional ion implantation process with the stacked gate structure 112 as an implantation mask.

The detail structure of the flash memory device of the present invention will be described as follow. Referring to FIG. 1D, a memory cell of the flash memory device comprises the substrate 100, the tunneling oxide layer 102a, the floating gate 108a, the inter-gate dielectric layer 106a, the control gate 110a, the source region 114a and the drain region 114b. In the structure of FIG. 1D, the floating gate 108a includes a plurality of nanocrystals. The stacked gate structure 112 includes the tunneling oxide layer 102a, the floating gate 108a, the inter-gate dielectric layer 106a and the control gate 110a.

Furthermore, the tunneling oxide layer 102a is disposed over the substrate 100. The material of the tunneling oxide layer 102a includes, for example, silicon oxide.

The floating gate 108a is disposed over the tunneling oxide layer 102a, and the material of the floating gate 108a includes, for example, Si_{X}Ge_{1-X} or metal silicide. In another embodiment of the present invention, the material of the floating gate 108a includes, for example, metal silicide, such as tungsten silicide, titanium silicide, cobalt silicide or nickel silicide. When the material of the floating gate 108a is tungsten silicide (W_{Y}Si_{Z}), the value of Y is about between 0.5 and 5, and the value of Z is about between 1 and 3.

The inter-gate dielectric layer 106a covers the nanocrystals (the floating gate 108a) and keeps the nanocrystals within the floating gate 108a. The material of the inter-gate dielectric layer 106a includes, for example, an oxide of the material of the floating gate 108a.

The structure of flash memory device further comprises a control gate 110a and a source/drain region 114a/114b. The control gate 110a is disposed over the inter-gate dielectric layer 106a, and a stacked gate structure 112 includes the tunneling oxide layer 102a, the floating gate 108a, the inter-gate dielectric layer 106a and the control gate 110a. Furthermore, the source/drain region 114a/114b is formed in the substrate 100 at each side of the stacked gate structure 112. When the material of the floating gate 108a is Si_{X}Ge_{1-X}, the material of the inter-gate dielectric layer 106a is silicon germanium oxide. When the material of the floating gate 108a is metal silicide, the material of the inter-gate dielectric layer 106a is metal silicon oxide.

In addition, the control gate 110a is disposed over the inter-gate dielectric layer 106a. The material of the control gate 110a includes, for example, doped polysilicon.

Furthermore, the source region 114a and the drain region 114b are formed in the substrate 100 at each side of the stacked gate structure 112.

As described above, the present invention at least comprises advantages as follow.

1. When the local region of the floating gate is impaired, only few of the crystals are impaired because the floating gate of the present invention includes the nanocrystals. Therefore, the charge storage or the charge transmission characteristic in the floating gate is not influenced, and thereby the failure issue of memory cells can be resolved.

2. In the flash memory device of the present invention, the nanocrystals in the floating gate can make hysteresis effect obvious, and thereby the ability of charge storage can be enhanced.

It will be apparent to those skilled in the art that various modifications and variations can be made to the structure of the present invention without departing from the scope or spirit of the invention. In view of the foregoing, it is intended that the present invention cover modifications and variations of this invention if they fall within the scope of the following claims and their equivalents.

1. A method for fabricating a flash memory device, comprising:
forming a tunneling oxide layer over a substrate;
forming a charge storage layer over the tunneling oxide layer; and
performing a thermal oxidation process so that a portion of the charge storage layer is oxidized to form an inter-gate dielectric material layer, while other portion of the charge storage layer not being oxidized is converted into a plurality of nanocrystals, wherein the nanocrystals form a floating gate.

2. The method of claim 1, wherein the step of forming the charge storage layer comprises forming a Si_{X}Ge_{1-X} layer or forming a metal silicide layer.

3. The method of claim 2, wherein the charge storage layer comprising Si_{X}Ge_{1-X} is formed by performing a low pressure chemical vapor deposition (LPCVD) process with a reactive gas of SiH₄ or GeH₄, under an operating pressure between 1 and 1000 mTorrs, and an operating temperature is between 600 and 800 degrees centigrade.

4. The method of claim 2, wherein the metal silicide layer comprises tungsten silicide, titanium silicide, cobalt silicide or nickel silicide.

5. The method of claim 4, wherein the charge storage layer comprises W_{Y}Si_{Z}, and the value of Y is between 0.5 and 5, and the value of Z is between 1 and 3.

6. The method of claim 5, wherein the charge storage layer is formed by performing a low pressure chemical vapor deposition (LPCVD) process with a reactive gas of WF₆, SiH₄, Si₂H₆, SiH₂Cl₂, or a composition thereof, under an operating pressure between 1 and 1000 mTorrs, and an operating temperature between 300 and 800 degrees centigrade.

7. The method of claim 1, wherein the thermal oxidation process comprises a rapid thermal oxidation process.

8. The method of claim 7, further comprising:
providing gases including oxygen during the rapid thermal oxidation process.

9. The method of claim 8, wherein the gases including oxygen comprises O₂, H₂O or NOₓ.

10. The method of claim 7, wherein a process temperature of the rapid thermal oxidation process is between 850 and 1000 degrees centigrade.

11. The method of claim 1, wherein the charge storage layer is formed by performing a low pressure chemical vapor deposition (LPCVD) process.

12. The method of claim 1, wherein the thermal oxidation process further comprises:
forming a control gate over the inter-gate dielectric layer, wherein a stacked gate structure includes the tunneling oxide layer, the floating gate, the inter-gate dielectric layer and the control gate; and
forming a source/drain region in the substrate at each side of the stacked gate structure.

13. A structure of a flash memory device comprises:
a substrate;
a tunneling oxide layer disposed over the substrate;
a floating gate disposed over the tunneling oxide layer, and the floating gate includes a plurality of nanocrystals; and
an inter-gate dielectric layer covering the nanocrystals and keeping the nanocrystals within the floating gate, wherein the material of the inter-gate dielectric layer is an oxide of the material of the floating gate.

14. The structure of claim 13, wherein the material of the floating gate comprises Si_{X}Ge_{1-X} or metal silicide.

15. The structure of claim 14, wherein the material of the metal silicide comprises tungsten silicide, titanium silicide, cobalt silicide or nickel silicide.

16. The structure of claim 15, wherein the material of the floating gate comprises W_{Y}Si_{Z}, and the value of Y is between 0.5 and 5, and the value of Z is between 1 and 3.

17. The structure of claim 13, further comprising:
a control gate disposed over the inter-gate dielectric layer, wherein a stacked gate structure includes the tunneling oxide layer, the floating gate, the inter-gate dielectric layer and the control gate; and
a source/drain region formed in the substrate at each side of the stacked gate structure.
